(19) United States
(12) Patent Application Publication
(10) Pub. No.: US 2020/0128671 A1
(43) Pub. Date: Apr. 23, 2020

(54) PRINTED CIRCUIT BOARD AND MOTOR INCLUDING THE SAME

(71) Applicant: Johnson Electric International AG, Murten (CH)

(72) Inventors: Youqing XIANG, Shenzhen (CN); Xiaojun YAN, Shenzhen (CN); Zhanqi ZHANG, Shenzhen (CN); Bailin BO, Shenzhen (CN); Minghua XIONG, Shenzhen (CN)

(21) Appl. No.: 16/586,094

(22) Filed: Sep. 27, 2019

(30) Foreign Application Priority Data
Sep. 30, 2018 (CN) 201811158613.2

(51) Int. Cl. H05K 1/16; H02K 3/28; H02K 3/26; H05K 1/18; H02K 11/02

(52) U.S. Cl. CPC H05K 1/165; H02K 3/28; H02K 3/26; H05K 2201/09218; H02K 11/02; H02K 2211/03; H05K 1/181

(57) ABSTRACT

A printed circuit board includes a substrate and an inductor, a first through hole defined in the substrate, the inductor including a magnetic core with a middle leg, the middle leg passes through the first through hole, and a conductive trace on at least one conductive layer of the printed circuit board spirally surrounds the first through hole to form conductive coil of the inductor. The present disclosure also provides a motor including a stator, a rotor, and the above described printed circuit board. The inductor is integrated with the printed circuit board, which reduces the size of the board and the motor and reduces material cost and power consumption.

### CROSS REFERENCE TO RELATED APPLICATIONS

This non-provisional patent application claims priority under 35 U. S. C. § 119(a) from Patent Application No. 201811158613.2 filed in the People's Republic of China on Sep. 30, 2018.

### FIELD OF THE INVENTION

The present disclosure relates to circuit boards, and more particularly to a printed circuit board and a motor including the same.

### BACKGROUND OF THE INVENTION

Traditional coil inductors are commonly soldered to a printed circuit board (PCB). Traditional coil inductors typically comprising of copper wire coils wounded on a core, that increases the PCB's size and additional power consumption, and its open magnetic circuitry also reduces the electromagnetic interference (EMI) performance of the PCB.

### SUMMARY

In view of the above, it is necessary to provide a PCB and a motor including the same that can solve the above problems.

According to one aspect, a printed circuit board includes a substrate and an inductor, a first through hole is defined in the substrate, the inductor includes a magnetic core with a middle leg, the middle leg passes through the first through hole, and a conductive trace on at least one conductive layer of the printed circuit board spirally surrounds the first through hole to form conductive coil of the inductor.

Preferably, the magnetic core includes an upper magnetic core, the upper magnetic core includes a bottom plate and two side legs perpendicular to the bottom plate, the two side legs are disposed on opposite ends of the bottom plate, and the middle leg is disposed at a middle portion of the bottom plate.

Preferably, a side wall of the side leg facing the middle leg has an arcuate recess.

Preferably, the upper magnetic core is E-shaped.

Preferably, two second through holes for the two side legs passing through are defined in the substrate.

Preferably, the magnetic core further comprises a lower magnetic core disposed opposite the upper magnetic core, the upper and lower magnetic cores are disposed on opposite surfaces of the substrate respectively, and the lower magnetic core is in contact with the side legs of the upper magnetic core, and a gap is formed between the lower magnetic core and the middle leg of the upper magnetic core.

Preferably, the conductive trace surrounding the first through hole has a spiral shape and is disposed between the two second through holes, both ends of the conductive trace are electrically connected to other conductive trace of the printed circuit board without solder joints.

Preferably, one end of the conductive trace on a conductive layer is electrically connected to the conductive trace on another conductive layer of the printed circuit board through vias.

Preferably, material for manufacturing the magnetic core comprises Fe₂O₃, Mn₃O₄, ZnO.

Preferably, comprising at least one capacitor mounted to the substrate by a mounting bracket, the mounting bracket including at least one latching arm for engaging the capacitor.

According to another aspect, a motor includes a stator, a rotor, and a printed circuit board described above.

Preferably, the motor further including a support member and a bottom cover, wherein the stator is fixed to one side of the support member, the bottom cover is fixed to opposite side of the support member, the bottom cover and the bottom end of the support member together form a receiving space, and the printed circuit board is received in the receiving space.

Preferably, a recess is defined in the support member facing the printed circuit board for accommodating electronic components, and heat dissipation fins are formed on the support member toward the stator.

In the PCB of the present disclosure and the motor including the same, the magnetic core of the inductor is integrated with the PCB, and the conductive trace of the PCB replaces the conventional copper wire coils wound around the magnetic core. Compared with traditional coil inductors, the self-inductance factor of the inductor can be increased by 80% or more, the size of the PCB, material cost and power consumption are reduced.

### BRIEF DESCRIPTION OF THE DRAWINGS

FIG. 1 is a schematic view of an embodiment of a PCB of the present disclosure.

FIG. 2 is a schematic view of a magnetic core of an inductor of the PCB shown in FIG. 1.

FIG. 3 is a plan view of a substrate of the PCB shown in FIG. 1.

FIG. 4 is a schematic view showing the conductive trace of a bottom surface of the substrate of the PCB shown in FIG. 1.

FIG. 5 is a cross-sectional view of the PCB of FIG. 1 taken along line A-A.

FIG. 6 is a schematic view of an embodiment of a motor of the present disclosure.

FIG. 7 is an exploded view of the motor of FIG. 6.

### DETAILED DESCRIPTION OF THE PREFERRED EMBODIMENTS

The subject matter will be described in conjunction with the accompanying drawings and the preferred embodiments. The described embodiments are only a few and not all of the embodiments of the present disclosure. All other embodiments obtained by those ordinarily skilled in the art based on the embodiments of the present disclosure without any creative efforts fall within the protection scope of the present disclosure. It is to be understood that, the drawings are provided for reference only and are not intended to be limiting of the invention. The dimensions shown in the drawings are only for convenience of illustration and are not intended to be limiting.

It should be noted that when a component is considered to be “connected” to another component, it can be directly connected to another component or may also have a centered component. Unless otherwise defined, all technical and scientific terms used herein have the same meaning as commonly understood by those ordinarily skilled in the art. The terminology used in the specification of the present disclosure is only for the purpose of describing particular embodiments and is not intended to limit the invention.

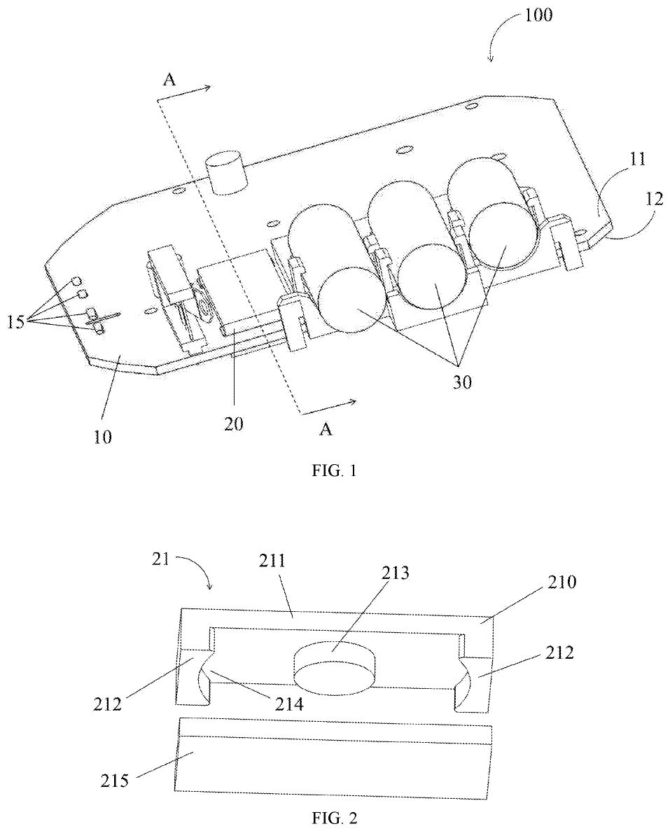

Referring to FIG. 1 to FIG. 4, a printed circuit board (PCB) 100 of the present disclosure includes a substrate 10 and an inductor 20. The inductor 20 is integrated with the substrate 10. The substrate 10 includes a first surface 11 and a second surface 12 opposite to the first surface 11. The inductor 20 includes a magnetic core 21 and a conductive coil 22.

FIG. 2 shows the structure of the magnetic core 21 of the inductor 20. The magnetic core 21 includes an upper magnetic core 210 and a lower magnetic core 215. The upper magnetic core 210 is substantially E-shaped and includes a bottom plate 211, two side legs 212, and a middle leg 213 perpendicular to the bottom plate 211. In this embodiment, the two side legs 212 are disposed at opposite ends of the bottom plate 211, and the middle leg 213 is disposed at a middle portion of the bottom plate 211. The extended length of the side leg 212 is greater than that of the middle leg 213. In this embodiment, the middle leg 213 has a cylindrical shape, and its axial line coincides with a center line of the bottom plate 211. The side leg 212 has a rectangular cross section, and a side wall facing the middle core 213 has an arcuate recess 214. The recess 214 is preferably concentric with the middle leg 213. In the present embodiment, the lower magnetic core 215 has an I-shape or a flat shape and has the same length and width as the bottom plate 211. Preferably, materials for manufacturing the magnetic core 21 include a ferrite constituent material such as Fe₂O₃, Mn₃O₄, and ZnO. With such a material, the efficiency of the magnetic core can be improved.

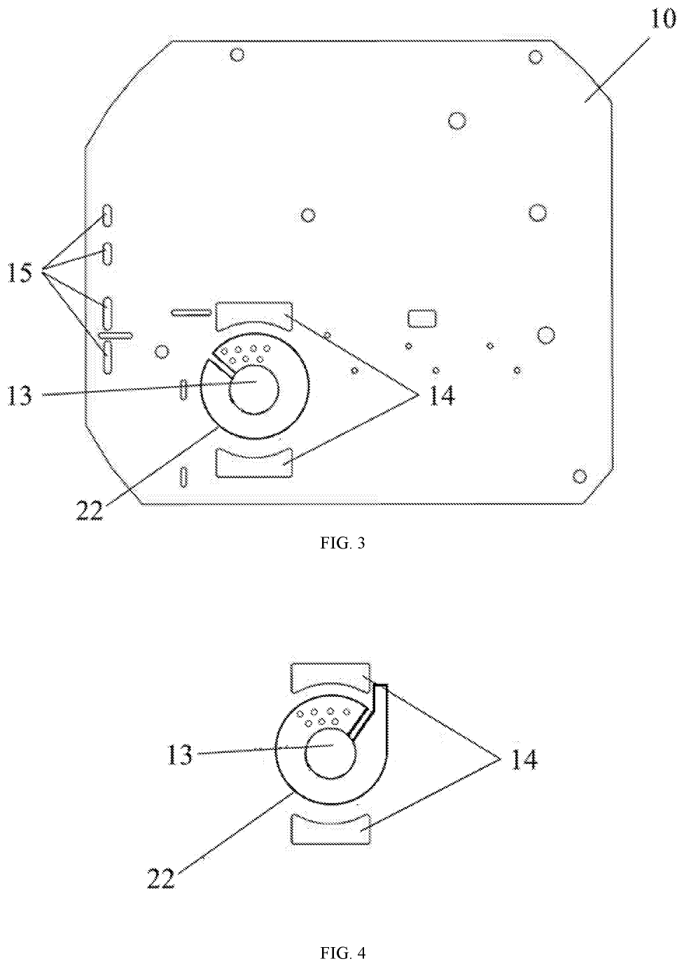

FIG. 3 shows a top view of the substrate 10. A first through hole 13 and two second through holes 14 are defined in the substrate 10 penetrating the first surface 11 and the second surface 12 for mounting the magnetic core 21 of the inductor 20. In the present embodiment, the first through hole 13 corresponds to the middle leg 213, which is preferably a circular hole whose diameter is equal to or slightly larger than the diameter of the middle leg 213. The two second through holes 14 are disposed on opposite sides of the first through hole 13, and have a shape matching the shape of the side leg 212. A diameter of the second through hole 14 is equal to or slightly larger than the that of the side leg 212. And a conductive trace 22 (such as a copper foil) of at least one conductive layer of the substrate 10 is etched to form a spiral conductive coil surrounding the periphery of the first through hole 13 and located between the two second through holes 14. Two ends of the conductive trace 22 are electrically connected to other circuits on the substrate 10 through traces etched on the substrate to provide current paths. Preferably, one end of the conductive trace on one conductive layer (such as the top layer) can be connected to conductive trace of other conductive layer (such as the bottom layer) (see FIG. 4) through vias. In other embodiments, when the PCB is a multi-layer circuit board, the conductive trace 22 may be disposed on multiple conductive layers in the PCB, and may surround the middle leg 213 along the extending direction of the middle leg across the plurality of conductive layers. The conductive trace of each layer has a C shape. The PCB being a two-layer board is taken as an example. The conductive trace on the top surface is referred to as a first conductive trace, and the conductive trace on the bottom surface is referred to as a second conductive trace. Each of the first and second conductive traces has a first end and a second end along a clockwise or counterclockwise direction, the second end of the first conductive trace is substantially aligned with the first end of the second conductive trace. Conductive paths between the first and second conductive traces are formed from solder-filled vias passing through the second end of the first conductive trace and the first end of the second conductive trace. Connecting the conductive traces of different conductive layers through a plurality of vias can increase the current and reduce the impedance.

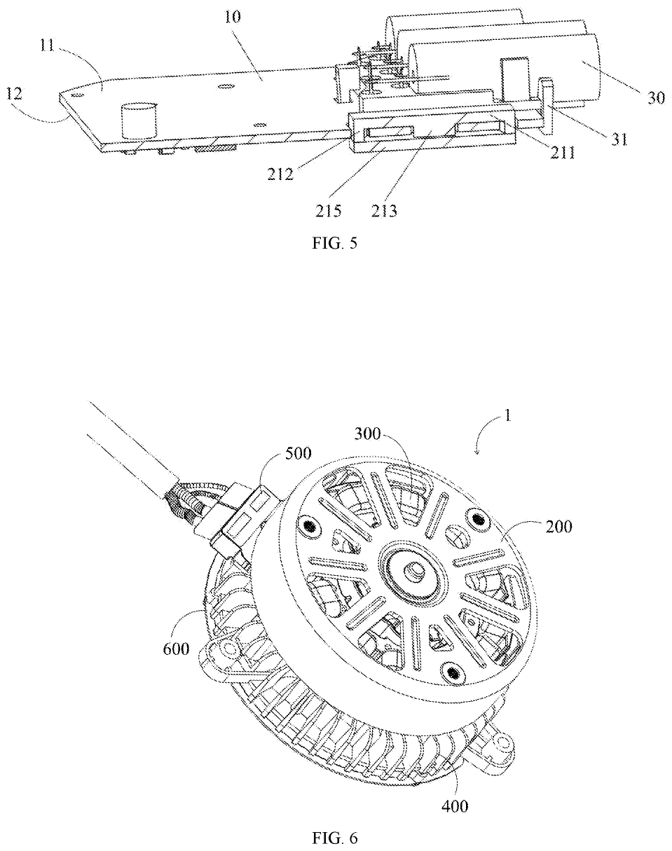

Referring to FIG. 3 and FIG. 5, when assembly, the side legs 212 of the magnetic core 21 are inserted from the first surface 11 of the substrate 10 into the second through holes 14 and exposed from the second surface 12. The middle leg 213 of the magnetic core 21 is also inserted from the first surface 11 of the substrate 10 into the first through hole 13 and exposed from the second surface 12. The upper magnetic core 210 and the lower magnetic core 215 are fixed by adhesive, the side legs 212 are in contact with the lower magnetic core 215, and a gap is formed between the middle leg 213 and the lower magnetic core 215. The magnetic core 21 cooperates with the conductive trace 22 on the PCB to form the inductor, and the side legs 212 contact the lower magnetic core 215 to form a closed magnetic circuit, which can improve the EMI performance of the inductor. The gap between the middle leg 213 and the lower magnetic core 215 can effectively avoid magnetic saturation when the current in the conductive trace 22 is increased, and improve the power of the inductor. Preferably, adhesive can also be injected into the gap to increase the fixing strength of the magnetic core 215. It can be understood by those skilled in the art that in other embodiments, the shape of the upper and lower magnetic cores may be other shapes, such as the upper magnetic core 210 is E-shaped, the lower magnetic core 215 is also E-shaped, and the joint of the upper and lower magnetic cores may be located inside the substrate 10; or the upper magnetic core 210 is U-shaped, the lower magnetic core 215 is U-shaped or I-shaped. The middle leg 213 may also have the same extension length as the side leg 212 and be in contact with the lower magnetic core 215. The inductor integrated with the PCB not only saves the wiring space of the circuit board, but also avoids manual installation of the inductor component, simplifies the assembly operation. No need to have solder joints for mounting the inductor on the PCB, thereby reducing the probability of soldering failure and improving product reliability.

In addition, other electronic components (not shown) for realizing power supply and signal processing functions are mounted on the substrate 10, and connectors for connecting the PCB 100 to an external power source and/or for transmitting signals are mounted on the substrate 10. Preferably, capacitors 30 are mounted on the substrate 10 through a mounting bracket 31. The mounting bracket 31 spaces the capacitors 30 from the substrate 10. Pins of the capacitor 30 penetrate the mounting bracket and are inserted into the PCB and electrically connected to trace of the PCB 100. Preferably, the capacitor 30 is arranged in parallel with the substrate 10, that is, the axis of the capacitor 30 is parallel to the surface of the substrate 10, such that not only reducing the height of the circuit board assembly, but also facilitating cooperation with the heat sink to improve heat dissipation efficiency. In this embodiment, the mounting bracket includes receiving slots for accommodating the capacitors, and two latching arms disposed on both sides of each receiving slot perpendicular to the substrate 10. A hook is disposed on an end of the latching arm for fixing the capacitor. When the capacitor 30 is accommodated in the receiving slot of the mounting bracket, the hooks of the latching arms 31 press on the outer peripheral surface of the capacitor, thereby fixing the capacitor. In this embodiment, a plurality of cylindrical capacitors is mounted on the circuit board, which is in parallel with each other, and preferably also parallel to the extending direction of the bottom plate 211 of the magnetic core 21.

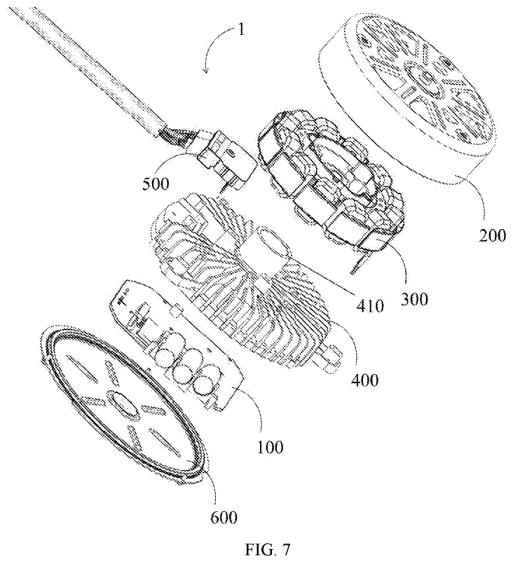

Referring to FIGS. 6 and 7, a motor 1 including the PCB of the present disclosure and its specific structure are shown. The motor 1 includes a rotor 200, a stator 300, a support member 400, a PCB 100, a connector 500, and a bottom cover 600, wherein the PCB 100 is a PCB in accordance with the present disclosure. The stator 300 is fixed to a fixing post 410 of the support member 400, and the rotor 200 is rotatably around the periphery of the stator 300. To facilitate stable rotation of the rotor 200, the rotating shaft of the rotor 200 may be supported by bearings disposed in the fixed posts 410 of the support member 400. The bottom cover 600 is fixed to the bottom of the support member 400 to form a receiving space at the lower end of the support member 400. The PCB 100 is received in the receiving space and fixed to the bottom cover 600. The conductive terminals of the connector 500 passes through the support member 400 from an upper end of the support member 400 and are fixed to the insertion holes 15 of the PCB 100. The support member 400 is provided with a plurality of recesses toward the circuit board for accommodating large-sized components such as capacitors and inductors. The support member 400 is provided with a plurality of heat dissipation fins facing the stator to increase the heat dissipation area.

In the PCB of the present disclosure and the motor using the same, the magnetic core of the inductor is integrated with the PCB, and the conventional copper wire wound on the magnetic core is replaced with the trace of the PCB. Compared with PCBs including conventional inductors, the self-inductance factor can be increased by 80% or more, the size of the PCB and the motor are reduced, and material cost and power consumption are reduced.

The above is only a preferred embodiment of the present invention, and the scope of the present invention is not limited to the above-exemplified embodiments, and any one skilled in the art can clearly obtain the technology within the technical scope disclosed by the present invention. Simple variations or equivalent substitutions of the schemes are all within the scope of the invention.

1. A printed circuit board comprising a substrate and an inductor, a first through hole defined in the substrate, the inductor comprising a magnetic core with a middle leg, wherein the middle leg passes through the first through hole, and a conductive trace on at least one conductive layer of the printed circuit board spirally surrounds the first through hole to form conductive coil of the inductor.

2. The printed circuit board according to claim 1, wherein the magnetic core comprises an upper magnetic core, the upper magnetic core comprises a bottom plate and two side legs perpendicular to the bottom plate, the two side legs are disposed on opposite ends of the bottom plate, and the middle leg is disposed at a middle portion of the bottom plate.

3. The printed circuit board according to claim 2, wherein a side wall of the side leg facing the middle leg has an arcuate recess.

4. The printed circuit board according to claim 2, wherein the upper magnetic core is E-shaped.

5. The printed circuit board according to claim 2, wherein two second through holes for the two side legs passing through are defined in the substrate.

6. The printed circuit board according to claim 5, wherein the magnetic core further comprises a lower magnetic core disposed opposite the upper magnetic core, the upper and lower magnetic cores are disposed on opposite surfaces of the substrate respectively, and the lower magnetic core is in contact with the side legs of the upper magnetic core, and a gap is formed between the lower magnetic core and the middle leg of the upper magnetic core.

7. The printed circuit board according to claim 5, wherein the conductive trace surrounding the first through hole has a spiral shape and is disposed between the two second through holes, both ends of the conductive trace are electrically connected to other conductive trace of the printed circuit board without solder joints.

8. The printed circuit board according to claim 7, wherein one end of the conductive trace on a conductive layer is electrically connected to the conductive trace on another conductive layer of the printed circuit board through vias.

9. The printed circuit board according to claim 1, wherein material for manufacturing the magnetic core comprises Fe₂O₃, Mn₃O₄, ZnO.

10. The printed circuit board according to claim 1, further comprising at least one capacitor mounted to the substrate by a mounting bracket, the mounting bracket including at least one latching arm for engaging the capacitor.

11. A motor comprising a stator, a rotor, and a printed circuit board according to claim 1.

12. The motor according to claim 11, further comprising a support member and a bottom cover, wherein the stator is fixed to one side of the support member, the bottom cover is fixed to opposite side of the support member, the bottom cover and the bottom end of the support member together form a receiving space, and the printed circuit board is received in the receiving space.

13. The motor according to claim 12, wherein a recess is defined in the support member facing the printed circuit board for accommodating electronic components, and heat dissipation fins are formed on the support member toward the stator.

14. The motor according to claim 11, wherein the magnetic core comprises an upper magnetic core, the upper magnetic core comprises a bottom plate and two side legs perpendicular to the bottom plate, the two side legs are disposed on opposite ends of the bottom plate, and the middle leg is disposed at a middle portion of the bottom plate.

15. The motor according to claim 14, wherein the magnetic core further comprises a lower magnetic core disposed opposite the upper magnetic core, the upper and lower magnetic cores are disposed on opposite surfaces of the substrate respectively, and the lower magnetic core is in contact with the side legs of the upper magnetic core, and a gap is formed between the lower magnetic core and the middle leg of the upper magnetic core.

16. The motor according to claim 14, wherein the conductive trace surrounding the first through hole has a spiral shape and is disposed between the two second through holes, both ends of the conductive trace are electrically connected to other conductive trace of the printed circuit board without solder joints.
